(19) United States
(12) Patent Application Publication
(10) Pub. No.: US 2006/0037942 A1
(43) Pub. Date: Feb. 23, 2006

(54) Slurry, chemical mechanical polishing method using the slurry, and method of forming a surface of a capacitor using the slurry

(76) Inventors: Seong-Kyu Yun, Seoul (KR); Kenichi Orui, Ausugi-shi (JP); Chang-Ki Hong, Seongnam-si (KR); Jae-Dong Lee, Suwon-si (KR); Sung-Jun Kim, Suwon-si (KR); Haruki Nojo, Kouza-gun (JP)

Correspondence Address: HARNESS, DICKEY & PIERCE, P.L.C., P.O. BOX 8910, RESTON, VA, 20195, US

(21) Appl. No.: 11/170,061

(22) Filed: Jun. 30, 2005

(30) Foreign Application Priority Data
Aug. 17, 2004 (KR) 10-2004-0064648

(51) Int. Cl. C09K 13/00; C03C 15/00; H01L 21/302

(52) U.S. Cl. 216/88; 216/89; 252/79.1; 252/79.5; 438/692

(57) ABSTRACT

A slurry, chemical mechanical polishing (CMP) method using the slurry, and method of forming a surface of a capacitor using the slurry. The slurry may include an abrasive, an oxidizer, and at least one pH controller to control a pH of the slurry.

### PRIORITY STATEMENT

This application claims the benefit under 35 U.S.C. § 119(a) of Korean Patent Application No. 2004-0064648 filed on Aug. 17, 2004, the contents of which are hereby incorporated by reference in their entirety.

### BACKGROUND OF THE INVENTION

Ruthenium, including ruthenium alloys, such as ruthenium dioxide, may be used as a bottom electrode material of a capacitor for a semiconductor device. A ruthenium alloy may be defined as any composition where ruthenium is the main component. Ruthenium alloys, such as ruthenium dioxide, may have a lower surface resistance because of their conductivity, contrary to other materials, such as titanium oxide, tungsten oxide or tantalum oxide.

Conventionally, a ruthenium film may be deposited using a sputtering method or a CVD method, and afterward, some portion of the ruthenium film may be removed to form a bottom electrode by etching the ruthenium film. However, it may be difficult to etch a ruthenium film by conventional wet etch processes, using conventional etchants, including aqua-regia or a “piranha” etchant. A “piranha” etchant is a semiconductor industry-accepted term for a conventional wet chemical solution containing sulfuric acid and hydrogen peroxide, often used to clean substrates of organic contamination.

Another conventional solution for wet etching a ruthenium film is a solution including ceric ammonium nitrate, (NH₄)₂Ce(NO₃)₆, which can be used as a wet etchant or a chemical mechanical polish (CMP) slurry. However, ceric ammonium nitrate has several drawbacks. First, it may be difficult to control the removal rate of ruthenium because of ceric ammonium nitrate's high speed. Second, ceric ammonium nitrate may cause damage to processing machinery due to its high acidity (pH of about 1). Third, it may be difficult to control the pH of the wet etch solution because a precipitate is formed from the combination of cerium ions (Ce⁴⁺) and hydroxyl anions (OH⁻) and therefore it may also be difficult to control the selectivity between the ruthenium film(s) and other films.

Due to the above-mentioned problems with wet etching a ruthenium film, ruthenium films have also been etched using dry etch processes. However, dry etching ruthenium films may also have problems, including the formation of sharp cusps on a top surface of the ruthenium bottom electrode after node separation, recessing of the ruthenium bottom electrode and/or a loss of mold oxide, and a resultant loss of capacitance.

### SUMMARY OF THE INVENTION

Example embodiments of the present invention are directed to a slurry for a chemical mechanical polishing (CMP) method for polishing a metal film, such as an ruthenium film, which provides a high removal rate selectivity of metal film to other films, a polishing method, for example, a CMP method, using the slurry, and a method of forming a surface for a capacitor using the polishing method.

Example embodiments of the present invention are directed to a slurry, a polishing method, and a method of forming a surface for a capacitor with improved removal rate selectivity and/or better pH control.

Example embodiments of the present invention are directed to slurry for a chemical mechanical polishing (CMP) method for a film including ruthenium, the slurry including an abrasive, an oxidizer, and at least one pH controller to control a pH of the slurry.

Example embodiments of the present invention are also directed to a chemical mechanical polishing (CMP) method for a ruthenium film formed on a semiconductor substrate, the method including preparing a slurry including an abrasive, an oxidizer, and at least one pH controller to control a pH of the slurry and performing chemical mechanical polishing (CMP) of the ruthenium film using the slurry.

Example embodiments of the present invention are also directed to a method for forming a surface for a capacitor including forming an etch stop layer on a semiconductor substrate, forming a mold oxide layer on the etch stop layer, patterning the mold oxide layer to define a region for the capacitor, forming a layer including ruthenium on the patterned mold oxide layer, forming a dielectric layer on the layer including ruthenium, and polishing the layer including ruthenium and the dielectric layer using a slurry including an abrasive, an oxidizer, and at least one pH controller to control a pH of the slurry.

In example embodiments of the present invention, the capacitor is one of a stacked, concave, or OCS capacitor.

### BRIEF DESCRIPTION OF THE DRAWINGS

The present invention will become more fully understood from the detailed description given below and the accompanying drawings, which are given for purposes of illustration only, and thus do not limit the invention.

FIGS. 1-7 illustrate a method of forming a stacked capacitor using ruthenium or ruthenium alloy as a bottom electrode in accordance with example embodiments of the present invention.

FIGS. 8-17 illustrate a method of forming a concave capacitor using ruthenium or ruthenium alloy as a bottom electrode in accordance with example embodiments of the present invention.

FIG. 18 illustrate a One Cylinder Stack (OCS) structure capacitor in accordance with example embodiments of the present invention.

It should be noted that these Figures are intended to illustrate the general characteristics of methods and devices of example embodiments of this invention, for the purpose of the description of such example embodiments herein. These drawings are not, however, to scale and may not precisely reflect the characteristics of any given embodiment, and should not be interpreted as defining or limiting the range of values or properties of example embodiments within the scope of this invention.

In particular, the relative thicknesses and positioning of layers or regions may be reduced or exaggerated for clarity. Further, a layer is considered as being formed “on” another layer or a substrate when formed either directly on the referenced layer or the substrate or formed on other layers or patterns overlaying the referenced layer.

### DETAILED DESCRIPTION OF EXAMPLE EMBODIMENTS OF THE PRESENT INVENTION

In an example embodiment of the invention, a slurry for use in chemical mechanical polishing (CMP) may include an abrasive, an oxidizer, and/or a pH controller.

In an example embodiment, the abrasive may be ceria, silica (in any form, for example, colloidal or fumed silica), alumina, titania, angania, zirconia, germania or mixtures thereof.

In an example embodiment, the oxidizer may be or include periodic acid (H₅IO₆).

In an example embodiment, the pH controller may be or include an amine compound, for example, BHMT (Bis-(HexamMethylene)Triamine), TMAH (TetraMethyl Ammonium Hydroxide), TMA (TetraMethylAmine), TEA (TetraEthylAmine), HA (Hydroxylamine), PEA (PolyEthyleneAmine), CH (Choline Hydroxide) and/or choline salt. In other example embodiments, the pH controller may be potassium hydroxide.

In an example embodiment, the abrasive, for example, colloidal silica, may be from 0.01 to 30 (inclusive, as are all ranges disclosed and claimed herein) weight % of the CMP slurry, and more particularly, from 0.1 to 10 weight %, and more particularly, from 0.5 to 3.0 weight %.

In an example embodiment, the oxidizer, for example, periodic acid, may be from 0.1 to 5 weight % of the CMP slurry. In an example embodiment, a content of the oxidizer, for example, periodic acid, may be in a range from 2.5 to 5.0 weight % of a total weight of the slurry. In an example embodiment, a content of the oxidizer, for example, periodic acid, may be in a range from 0.1 to 2.0 weight % of a total weight of the slurry. In an example embodiment, a content of the oxidizer, for example, periodic acid, may be in a range from 0.1 to 1.0 weight % of a total weight of the slurry. In an example embodiment, a content of the oxidizer, for example, periodic acid, may be in a range from 0.1 to 0.5 weight % of a total weight of the slurry. In an example embodiment, a content of the oxidizer, for example, periodic acid, may be in a range from 0.25 to 0.5 weight % of a total weight of the slurry. In an example embodiment, a content of the oxidizer, for example, periodic acid, may be in a range from 0.5 to 1.5 weight % of a total weight of the slurry.

In an example embodiment, the pH of the CMP slurry is from 2 to 8 and more particularly, from 3.5 to 4.5. In an example embodiment, the pH of the CMP slurry is about 4. In another example embodiment, the pH of the CMP slurry is about 8.

In an example embodiment, a content of the colloidal silica is 0.5 weight % of a total weight of the slurry and a content of the periodic acid is 0.5 weight % of a total weight of the slurry. In an example embodiment, a content of the colloidal silica is 3 weight % of a total weight of the slurry and a content of the periodic acid is 0.5 weight % of a total weight of the slurry.

### EXAMPLE SLURRY 1

An example slurry according to the present invention includes colloidal silica and periodic acid. The periodic acid may act as an oxidizer of the ruthenium to form ruthenium dioxide on the surface of the ruthenium. The content range of the periodic acid may be from 0.1 weight % to 5 weight The content range of the periodic acid may be from 0.5 weight % to 1.5 weight %. The content range of the periodic acid may be from 0.1 to 5 weight The content range of the periodic acid may be from 2.5 to 5.0 weight %. The content range of the periodic acid may be from 0.1 to 2.0 weight %. The content range of the periodic acid may be from 0.1 to 1.0 weight %. The content range of the periodic acid may be from 0.1 to 0.5 weight %. The content range of the periodic acid may be from 0.25 to 0.5 weight %. The content range of the periodic acid may be from 0.5 to 1.5 weight %.

The colloidal silica may act as an abrasive. In addition to colloidal silica, other components such as ceria, alumina, titania, mangania, zirconia, germania or mixtures thereof can be used as an abrasive. The content range of the abrasive may be from 0.01 weight % to 30 weight %. The content range of the abrasive may be from 0.01 weight % to 1 weight %. The content range of the abrasive may be from 0.01 weight % to 1 weight % to raise the removal rate of other layers, including oxides, such as, Plasma-Tetra-Ortho-Silicate (TEOS), tantalum oxide (TaO), polysilicon, or silicon.

The CMP slurry may further include potassium hydroxide as a pH controller to increase the removal rate for ruthenium and decrease the removal rate for oxides, such as those mentioned above. In an example, the pH range may be from 2 to 8. In another example, the pH range may be from 3.5 to 4.5.

### COMPARATIVE EXAMPLE 1

The removal rates of ruthenium, TEOS, TaO, and polysilicon were measured as the pH of slurry was varied. In this example, the main components were 0.5 weight % colloidal silica of 15 nm in diameter and 0.5 weight % periodic acid. In this example, the pH was changed by using potassium hydroxide. The results are shown in Table 1.

TABLE 1

| | | R. R. of | R. R. of | | R. R. | R. R. of |
|---|---|---|---|---|---|---|
| | | ruthenium | TEOS | Selectivity | of TaO | polysilicon |
| No. | pH | (Å/min) | (Å/min) | (ru/TEOS) | (Å/min) | (Å/min) |
| 1 | 1.86 | 363 | 251 | 1.4 | >1,100 | 131 |
| 2 | 3.91 | 1,127 | 154 | 7.3 | 605 | 146 |
| 3 | 6.02 | >1,300 | 46 | >28 | 85 | 46 |
| 4 | 7.88 | >1,300 | 87 | >15 | 41 | 136 |

As shown in Table 1, the amount of potassium hydroxide may be increased to increase the pH of the CMP slurry. In sample No. 1, no potassium hydroxide is present. As shown in Table 1, the selectivity between ruthenium and other materials, like TEOS, TaO and polysilicon, may be controlled by changing the pH of the CMP slurry.

### EXAMPLE SLURRY 2

Another example slurry according to the present invention includes colloidal silica, periodic acid, and an amine compound, as a pH controller. The amine compound may increase the removal rate and selectivity between ruthenium and other materials, like TEOS, TaO, polysilicon, and silicon. The amine compound may be BHMT (Bis-(HexaMethylene)Triamine), TMAH (TetraMethyl Ammonium Hydroxide), TMA (TetraMethylAmine), TEA (TetraEthylAmine), HA (Hydroxylamine), PEA (PolyEthyleneAmine), CH (Choline Hydroxide) or choline salt. Other conditions may be the same as that of Example Slurry 1, except using an amine compound as a pH controller.

### COMPARATIVE EXAMPLE 2

The removal rates of ruthenium, TEOS, tantalum oxide (TaO) and polysilicon were measured as the amine compound was varied. In this example, the main components were 0.5 weight % colloidal silica of 15 nm in diameter, 0.5 weight % periodic acid and an amine compound that makes the pH of the slurry either 4 or 8. The results are shown in Table 2.

TABLE 2

| | | | | Removal | | Removal | |
|---|---|---|---|---|---|---|---|
| | | | Removal rate | rate of | | rate of | Removal rate of |
| | Amine | | of ruthenium | TEOS | Selectivity | TaO | polysilicon |
| No. | compounds | pH | (Å/min) | (Å/min) | (ru/TEOS) | (Å/min) | (Å/min) |
| 1 | None | 7.2 | 0 | 46 | — | 124 | 38 |
| 2 | TMAH | 4 | 892 | 86 | 10.4 | >1,200 | 2,314 |
| 3 | TEA | 4 | 262 | 148 | 1.8 | >1,200 | 614 |
| 4 | TEA | 8 | 0 | 16 | — | 22 | 1,308 |
| 5 | TMA | 4 | 866 | 144 | 6.0 | >1,200 | 2,136 |
| 6 | NH₄OH | 4 | 854 | 138 | 6.2 | 380 | 106 |
| 7 | NH₄OH | 8 | 746 | 92 | 8.1 | 38 | 170 |

As shown in Table 2, the amine compound may be varied to increase the selectivity of the CMP slurry. In sample No. 1, no amine compound or oxidizer was present. As shown in Table 2, the selectivity between ruthenium and other materials, for example, TEOS, TaO and polysilicon, may be controlled by changing the amine compound of the CMP slurry. As shown in Table 2, TMAH and TMA exhibit better results.

### COMPARATIVE EXAMPLE 3

The removal rates of ruthenium, TEOS, tantalum oxide (TaO) and silicon were measured as the pH of slurry changed by changing the amount of TMAH and TMA. The main components were 0.5 weight % colloidal silica of 15 nm in diameter, 0.5 weight % periodic acid and amine compound that makes the pH of the slurry either 4 or 8. The results are shown in Table 3.

TABLE 3

| | | | | Removal | | Removal | |
|---|---|---|---|---|---|---|---|
| | | | Removal Rate | Rate of | | Rate of | Removal Rate of |
| | pH | | of ruthenium | TEOS | Selectivity | TaO | silicon |
| No. | controller | pH | (Å/min) | (Å/min) | (ru/TEOS) | (Å/min) | (Å/min) |
| 1 | TMAH | 2 | 434 | 340 | 1.3 | >1,100 | 6,102 |
| 2 | | 3 | 647 | 134 | 4.8 | | 5,872 |
| 3 | | 4 | 869 | 116 | 7.5 | | 3,036 |
| 4 | | 5 | 939 | 408 | 2.3 | | 858 |
| 5 | TMA | 2 | 485 | 236 | 2.1 | | 744 |
| 6 | | 3 | 712 | 128 | 5.6 | | 2,328 |
| 7 | | 4 | 871 | 120 | 7.3 | | 2,246 |
| 8 | | 5 | 983 | 188 | 5.2 | | 1,852 |

As shown in Table 3, the removal rate of ruthenium increased as pH increased. Moreover, Table 3 shows that not only the removal rate of ruthenium, but also the removal rate of other layers, for example, TaO and silicon, can be controlled by changing the pH of the slurry.

### COMPARATIVE EXAMPLE 3

The removal rates of ruthenium, TEOS, tantalum oxide (TaO) and silicon were measured as the amount of colloidal silica was varied. The main components were colloidal silica of 15 nm in diameter, 0.5 weight % periodic acid and TMAH that makes the pH of the slurry about 4. The results are shown in Table 4.

TABLE 4

| | Amount of | | Removal | | | |
|---|---|---|---|---|---|---|
| | colloidal | Removal Rate | Rate of | | Removal Rate | Removal Rate |
| | silica | of ruthenium | TEOS | Selectivity | of TaO | of silicon |
| No. | (wt %) | (Å/min) | (Å/min) | (ru/TEOS) | (Å/min) | (Å/min) |
| 1 | 0 | 46 | 0 | — | 554 | 8 |
| 2 | 0.5 | 920 | 18 | 51.5 | >800 | 400 |
| 3 | 1 | 818 | 20 | 40.9 | >800 | 736 |
| 4 | 3 | 778 | 36 | 21.6 | >800 | 2,050 |
| 5 | 5 | 852 | 64 | 13.3 | >800 | 1,980 |
| 6 | 7 | 644 | 92 | 7.0 | >800 | 2,782 |
| 7 | 9 | 722 | 138 | 5.2 | >800 | 2,396 |

As shown in Table 4, the removal rate of TEOS increased, whereas the removal rate of ruthenium was not significantly affected as the amount of colloidal silica increased. In an example embodiment, a suitable amount of colloidal silica may be about 3 wt % taking the removal rate of silicon and the selectivity between ruthenium and TEOS into consideration.

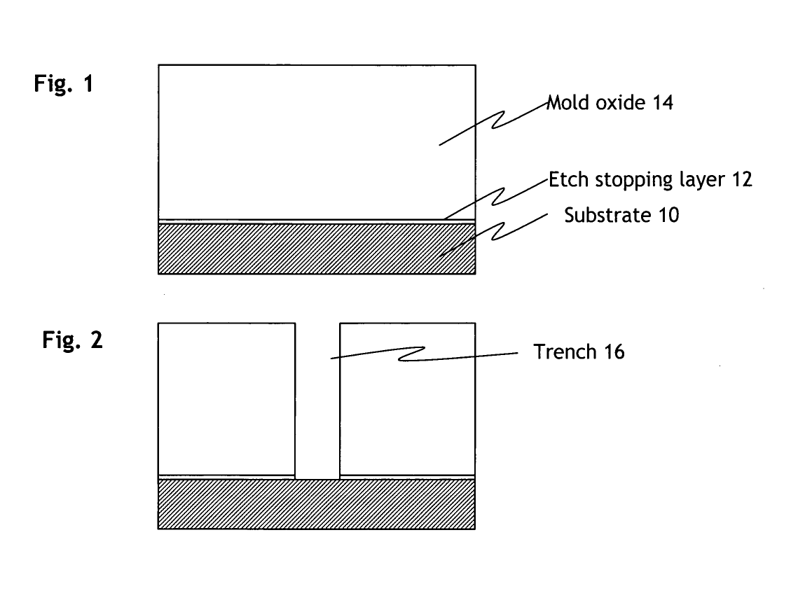

A method of forming a capacitor using ruthenium or ruthenium alloy as a bottom electrode in accordance with an example embodiment of the present invention is described in conjunction with FIG. 1-7. As shown in FIG. 1, the method may include depositing an etch stopping layer 12 and mold oxide layer 14 sequentially on a substrate 10.

As shown in FIG. 2, the method may further include defining a trench 16 for forming a capacitor by patterning the mold oxide layer 14. In an example embodiment, the patterning the mold oxide layer 14 may include using at least one of a hard mask and a photoresist. In an example embodiment, the mold oxide layer 14 may be one of a tetraethylorthosilicate (TEOS) layer, for example, a plasma enhanced TEOS (PE-TEOS) layer, an oxide (OX) layer, for example, a plasma enhanced OX (PE-OX) layer, a high density plasma (HDP) layer, an undoped silica glass (USG) layer, and a doped phosphosilicate glass (PG) layer, for example, boron-doped phosphosilicate glass (BPSG) layer.

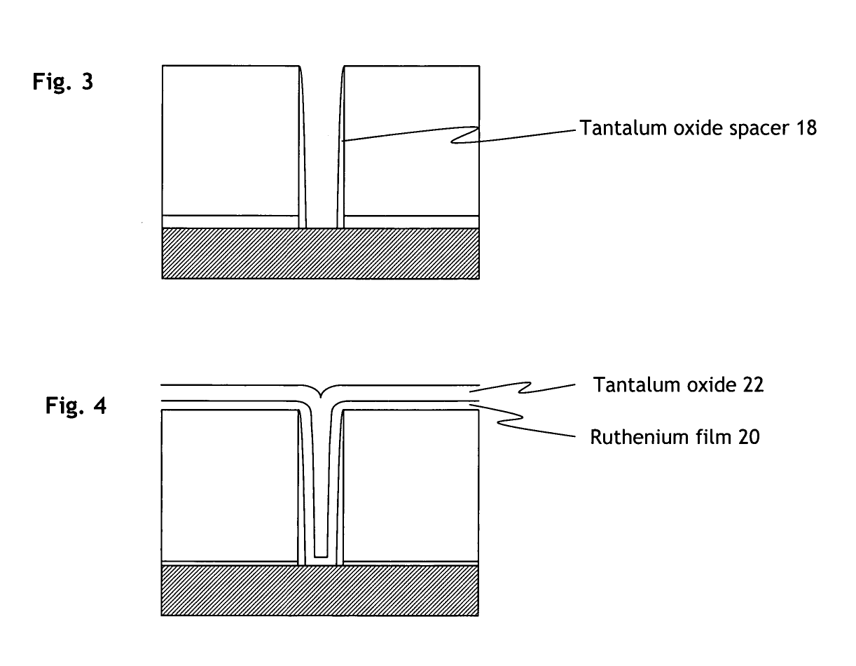

As shown in FIG. 3, the method may further include forming a space, for example, a tantalum oxide spacer 18 in the trench 16 and depositing a ruthenium film 20 in the trench 16, but not completely filling the trench 16, as shown in FIG. 4. In an example embodiment, the spacer 18 may include tantalum (Ta), hafnium (Hf), aluminium (Al), titanium (Ti), strontium titanate (Sb—Ti) of oxides (STO), barium strontium titanate (BST) or oxides or combinations thereof.

In an example embodiment, the ruthenium film 20 may be a ruthenium alloy. In an example embodiment, the ruthenium film 20 may be deposited by sputtering, chemical vapor deposition (CVD), or atomic layer deposition (ALD), all techniques commonly known in the semiconductor processing art.

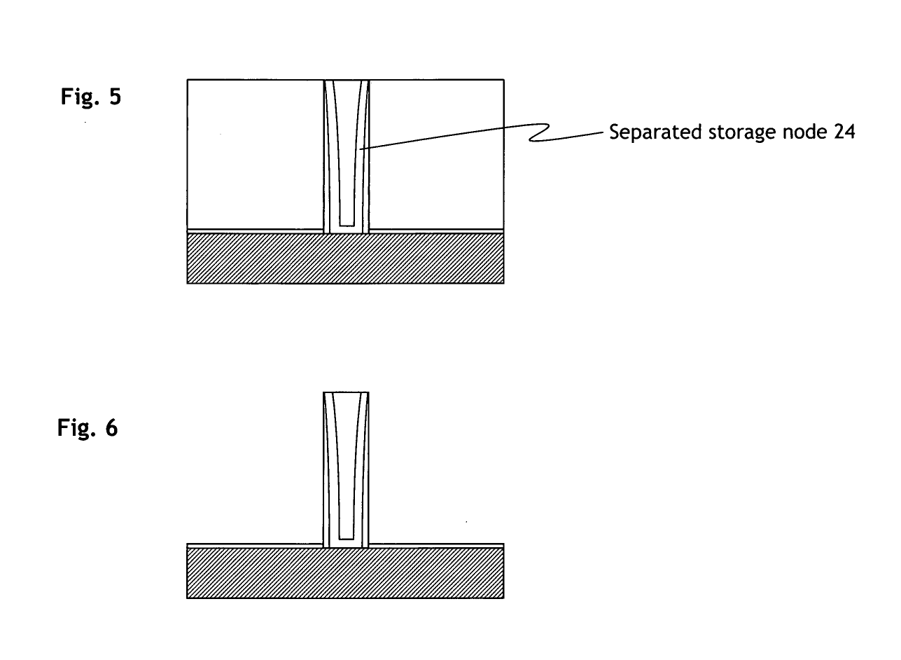

As also shown in FIG. 4, the method may further include depositing a layer, for example, a dielectric layer, for example, tantalum oxide 22 to completely fill the trench 16 and removing the tops of the ruthenium film 20 and the tantalum oxide layer 22 so that only the parts of the ruthenium film 20 and the tantalum oxide layer 22 in the trench remain to form a separated storage node 24, as shown in FIG. 5. In an example embodiment, the tops of the ruthenium film 20 and the tantalum oxide layer 22 may be removed by polishing using one or more of the slurries described above. In an example embodiment, the polishing is CMP polishing.

In an example embodiment, the dielectric layer may include tantalum (Ta), hafnium (Hf), aluminium (Al), titanium (Ti), strontium titanate (Sb—Ti) or oxides (STO), barium strontium titanate (BST) or oxides or combinations thereof.

In an example embodiment, the removal rate selectivity of the one or more of the slurries may be greater than or equal to 5:1. In other example embodiments, the removal rate selectivity may be greater than or equal to 20:1 or 50:1.

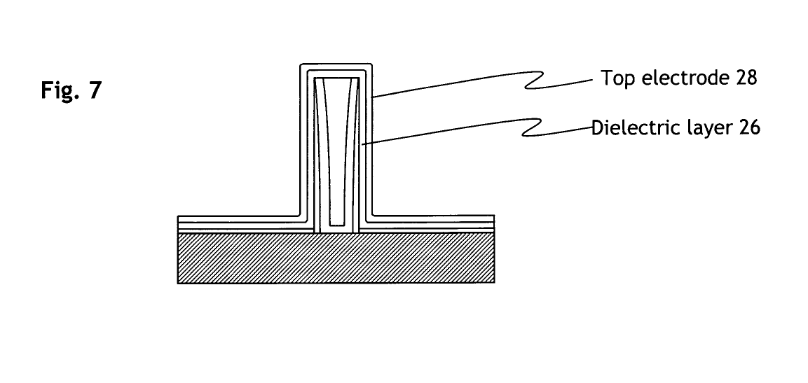

As shown in FIG. 6, the method may further include completely removing the mold oxide layer 14 to form a box-shaped bottom electrode structure and sequentially depositing a dielectric layer 26 and a top electrode layer 28, to thereby form a complete capacitor sequentially, as shown in FIG. 7.

Although, as shown in FIG. 7, the resulting capacitor may have a stacked structure, the example slurries and polishing methods in accordance with example embodiments of the present invention may be incorporated in other methods to form capacitors with different structures, for example, concave or OCS structures.

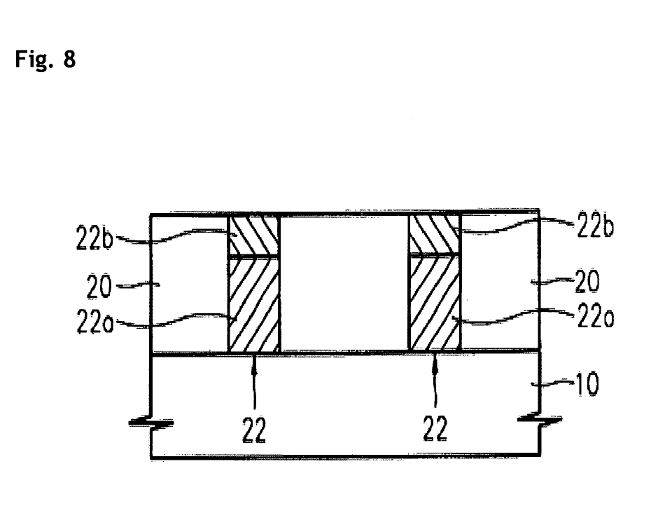

Another method of forming a capacitor using ruthenium or ruthenium alloy as a bottom electrode in accordance with an example embodiment of the present invention is described in conjunction with FIGS. 8-17. As shown in FIG. 8, a first interlayer dielectric film 20 may be formed on a semiconductor substrate 10, and a contact 22 may be connected to an active region of the semiconductor substrate 10 through the first interlayer dielectric film 20. In an example embodiment, the contact 22 may include a polysilicon layer 22a contacting the active region of the semiconductor substrate 10 and a contact plug 22b deposited on the polysilicon layer 22a and exposed on the first interlayer dielectric film 20. The contact plug 22b may serve as a barrier for reducing or preventing an undesired reaction from occurring between a lower electrode material and the polysilicon layer 22a in a subsequent thermal treatment process. The contact plug 22b may be formed of only the TiN layer, or can be formed of TiAlN, TiSiN, TaN, TaSiN, or TaAlN.

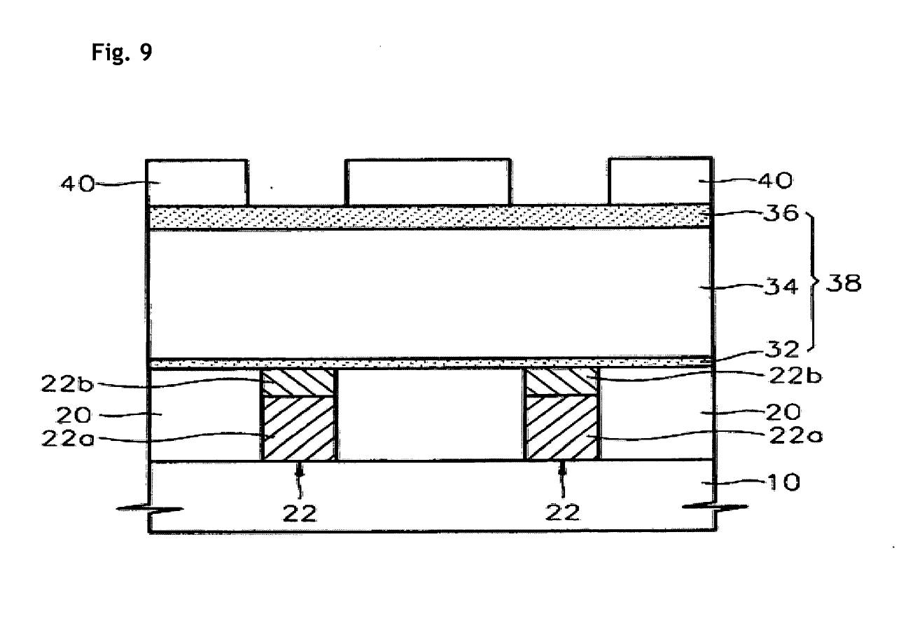

As shown in FIG. 9, a second interlayer dielectric film 38 comprising an etch stop layer 32, an oxide layer 34, and an anti-reflection layer 36 may be formed on the resultant structure on which the contact 22 is formed. In order to form the second interlayer dielectric layer 38, first, the etch stop layer 32, e.g., an SiN layer, may be formed to a thickness of about 50 to 100 Å on the upper surface of the first interlayer dielectric film 20 and an upper surface of the contact plug 22b which is the exposed surface of the contact 22. The oxide layer 34 having a thickness corresponding to a desired lower electrode height may be formed on the etch stop layer 32. The oxide layer 34 can be formed of any oxide that is typically used to form an interlayer dielectric film. An anti-reflection layer 36 made of SiON may be formed on the oxide layer 34. In an example, embodiment, a photoresist pattern 40 may be formed on the second interlayer dielectric film 38.

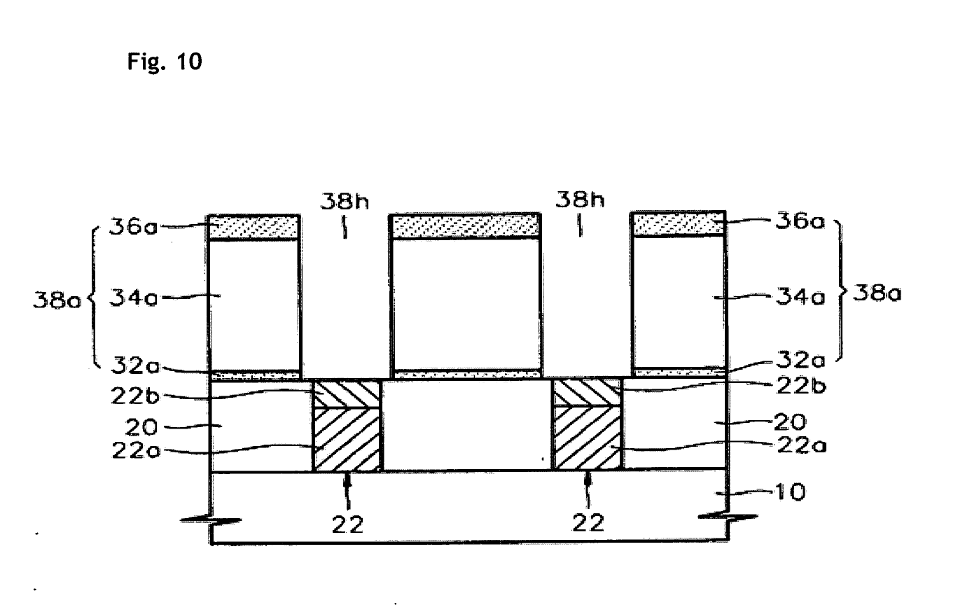

As shown in FIG. 10, the second interlayer dielectric film 38 may be etched up to the etch stop layer 32 which acts as an etch end point using the photoresist pattern 40 as an etch mask. As a result, a concave pattern 38a may be formed. A portion formed on the contact 22 among the etch stop layer 32 used as the etch end point may be completely removed by over etching. As a result, the concave pattern 38a may include an etch stop layer pattern 32a, an oxide layer pattern 34a and an anti-reflection layer pattern 36a, and a storage node hole 38h exposing the upper surface of the contact 22. Thereafter, the photoresist pattern 40 may be removed.

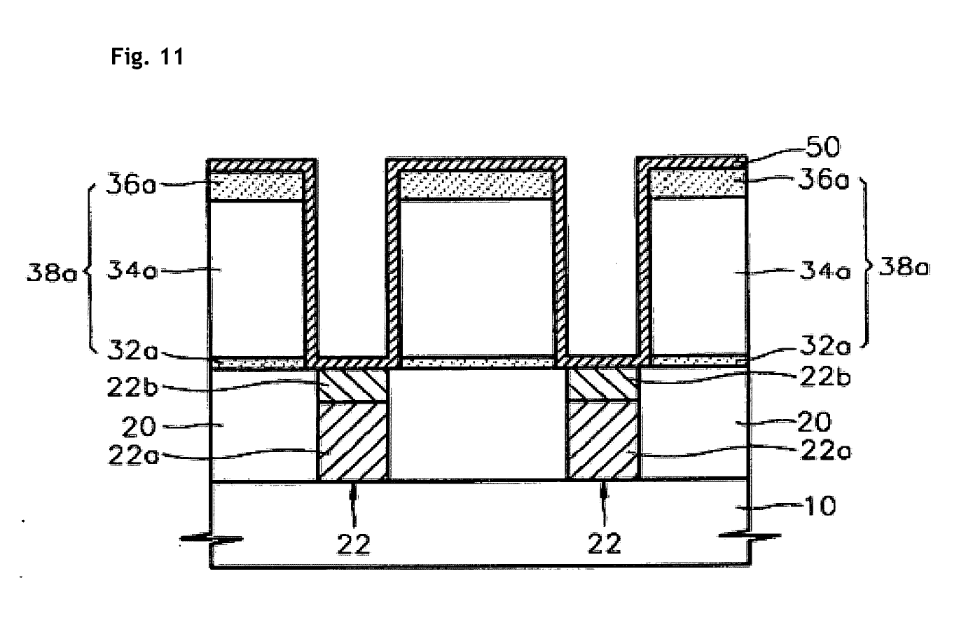

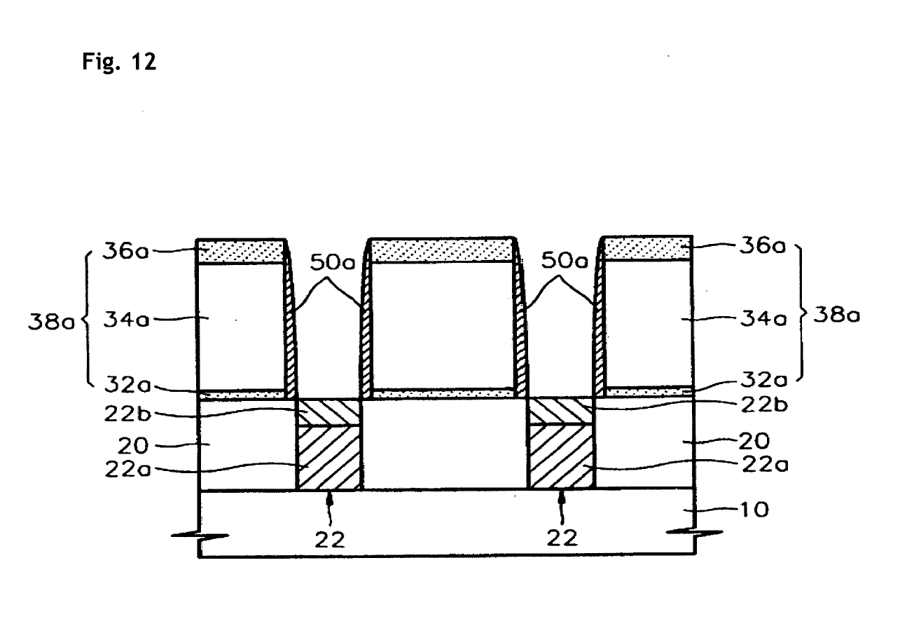

FIGS. 11 and 12 are cross-sectional views illustrating the formation of an adhesion spacer 50a for improving the bonding between the concave pattern 38a and a lower electrode formed in a subsequent process, on the sidewalls of the concave pattern 38a exposed by the storage node hole 38h, in accordance with an example embodiment of the present invention.

In more detail, in FIG. 11, an adhesion layer 50 may be formed to cover the contact 22 exposed by the storage node hole 38h, and the sidewall and upper surface of the concave pattern 38a. The adhesion layer 50 can be formed of at least one material selected from the group consisting of Ti, TiN, TiSiN, TiAlN, TiO₂, Ta, Ta₂O₅, TaN, TaAlN, TaSiN, Al₂O₃, W, WN, Co, and CoSi, using a chemical vapor deposition (CVD) method, a physical vapor deposition (PVD) method, a metal-organic deposition (MOD) method, a sol-gel method, or an atomic layer deposition (ALD) method.

In accordance with an example embodiment of the present invention, the adhesion layer 50 may undergo an etchback process until the adhesion spacer 50a remains on only the sidewall of the concave pattern 38a. Thus, only the adhesion spacer 50a and the contact 22 are exposed within the storage node hole 38h.

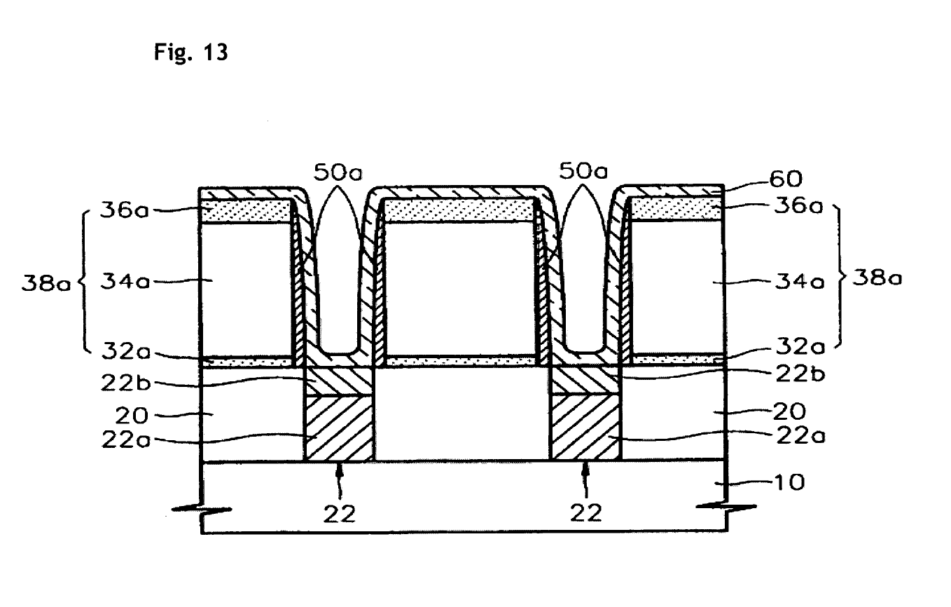

FIGS. 13-16 are cross-sectional views illustrating the formation of a lower electrode 60a in the storage node hole 38h, in accordance with an example embodiment of the present invention.

As shown in FIG. 13, a first conductive layer 60 may be formed to cover the upper surface of the contact 22 and the adhesion spacer 50a which are exposed within the storage node hole 38h, and the upper surface of the concave pattern 38a.

The first conductive layer 60 can be formed by depositing a platinum-group metal, a platinum-group metal oxide, or a material having a perovskite structure using a PVD or CVD method. For example, the first conductive layer 60 can be formed of Pt, Ru, Ir, RuO₂, IrO₂, SrRuO₃, BaSrRuO₃, or CaSrRuO.

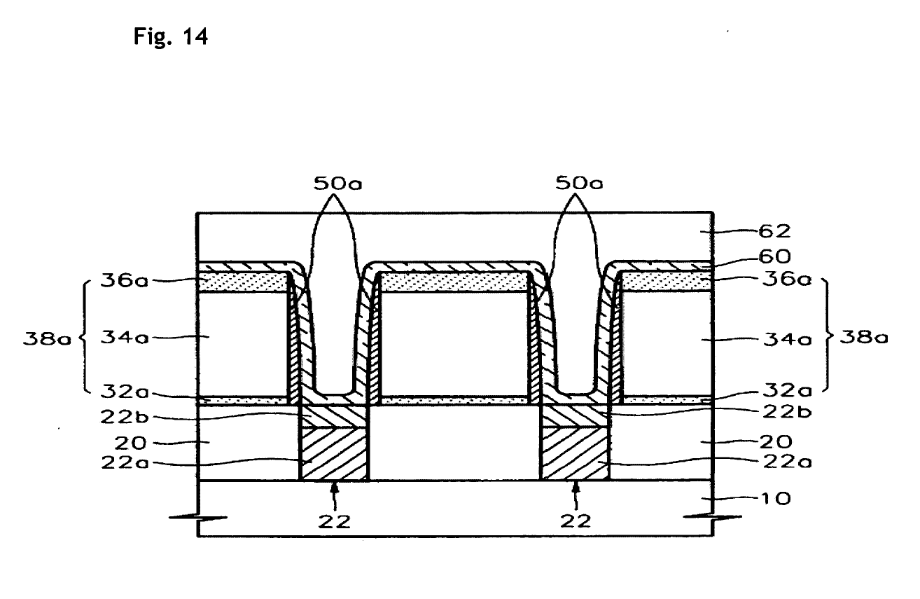

In an example embodiment, as shown in FIG. 14, a sacrificial layer 62 having a thickness which can sufficiently fill the storage node hole 38h may be formed on the resultant structure on which the first conductive layer 60 has been formed. The sacrificial layer 62 can be a photoresist layer or an oxide layer.

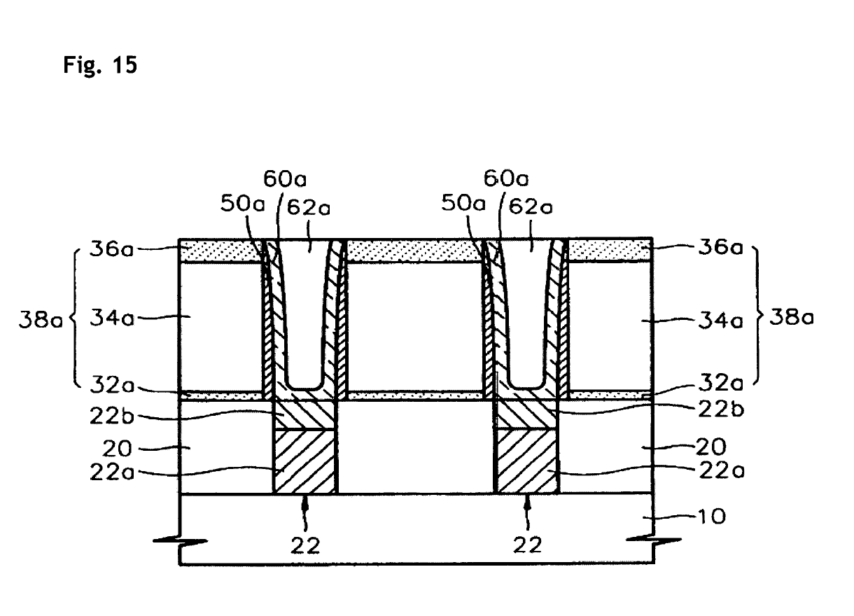

The first conductive layer 60 and sacrificial layer 62 on the concave pattern 38a may be etched back or removed by chemical mechanical polishing (CMP) until the upper surface of the concave pattern 38a is exposed. Consequently, the first conductive layer 60 may be divided into a plurality of lower electrodes 60a as shown in FIG. 15. Each of the lower electrodes 60a may cover the upper surface of the contact 22, and the adhesion spacer 50a in the storage node hole 38h.

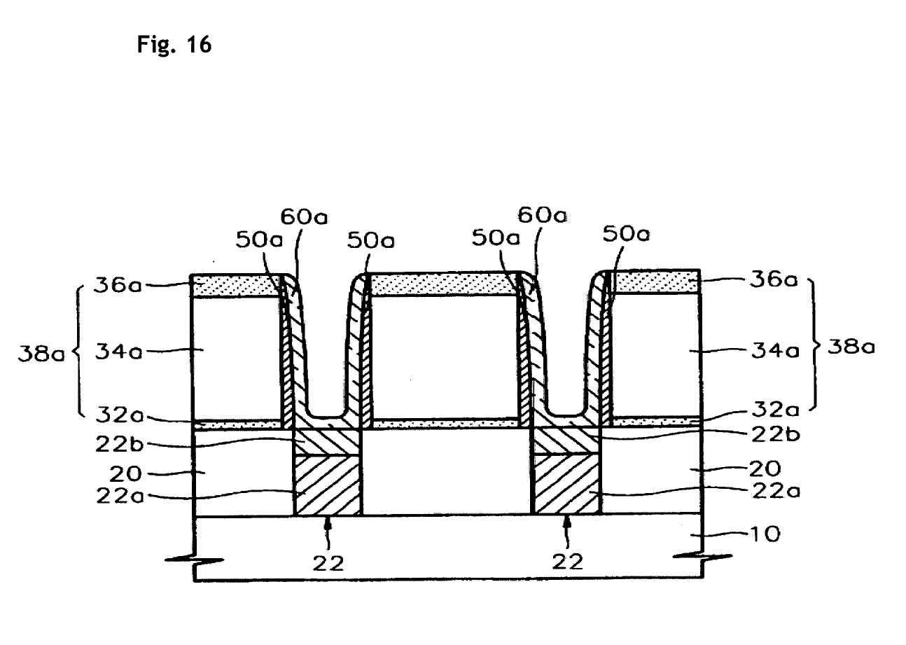

In the storage node hole 38h, the residual portion 62a of the sacrificial layer 62 may remain on the lower electrode 60a. The residual portion 62a of the sacrificial layer 62 may be removed by ashing or wet etch, thus obtaining a resultant structure as shown in FIG. 16. In an example embodiment, when the sacrificial layer 62 is a photoresist layer, the residual portion 62a of the sacrificial layer 62 may be removed by ashing. In an example embodiment, when the sacrificial layer 62 is an oxide layer, the residual portion 62a of the sacrificial layer 62 may be wet-etched out.

In an example embodiment, the photoresist layer or oxide layer forming the sacrificial layer 62 can be removed at an excellent selectivity with respect to SiON forming the anti-reflection layer pattern 36a in the upper portion of the concave pattern 38a and a conductive material forming the lower electrode 60a. Therefore, when the residual portion 62a of the sacrificial layer 62 is removed, other portions on the semiconductor substrate 10 are not damaged.

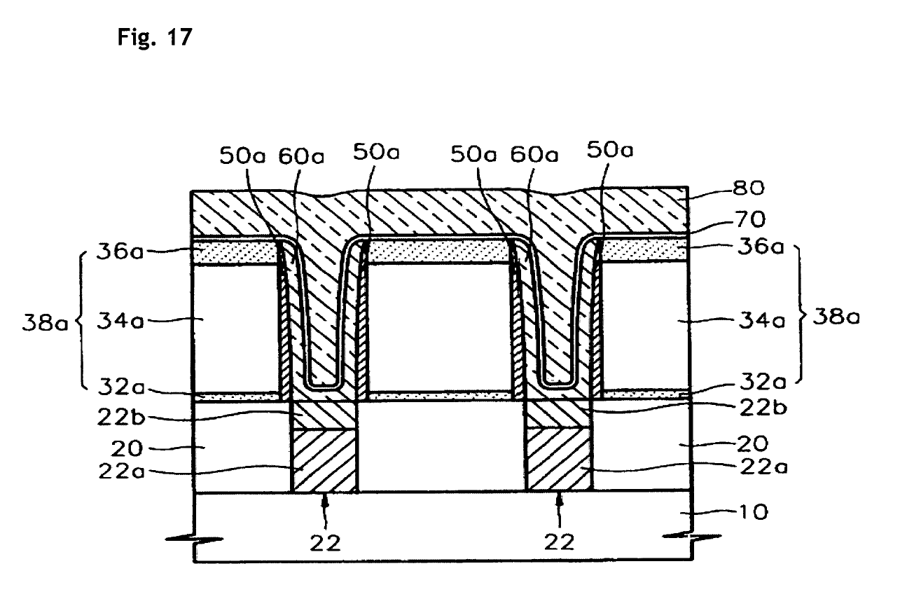

Referring to FIG. 17, a dielectric layer 70 may be formed on the lower electrode 60a. The dielectric layer 70 may be formed of at least one material selected from the group consisting of Ta₂O₅, Al₂O₃, SiO₂, SrTiO₃, BaTiO₃, (Ba,Sr)TiO₃, PbTiO₃, (Pb,Zr)TiO₃, Pb(La,Zr)TiO₃, Sr₂Bi₂NbO₉, Sr₂Bi₂ TaO₉, LiNbO₃, and Pb(Mg,Nb)O₃. In an example embodiment, the dielectric layer 70 may be formed by the PVD method, the CVD method, or the sol-gel method.

In an example embodiment, a second conductive layer 80 may be formed on the dielectric layer 70, thus forming an upper electrode of a capacitor. The second conductive layer 80 may be formed by depositing a platinum-group metal, a platinum-group metal oxide, TiN, or a material having a perovskite structure using the PVD method, the CVD method, the MOD method, or the ALD method. For example, the second conductive layer 80 can be formed of Pt, Ru, Ir, RuO₂, IrO₂, TiN, SrRuO₃, BaSrRuO₃, or CaSrRuO₃.

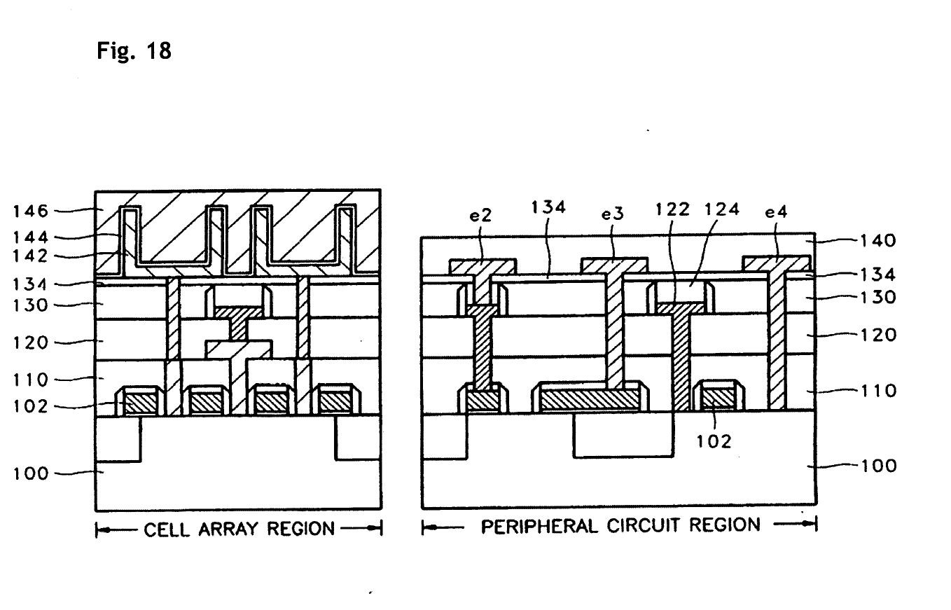

FIG. 18 illustrates a storage electrode 142 formed in a One Cylinder Stack (OCS) structure, in accordance with an example embodiment of the present invention. As shown in FIG. 18, an OCS capacitor may include a bit line 122 and a first capping layer 124 on an integrated circuit substrate 100.

In an example embodiment, the first capping layer 124 may cover the bit line 122. The bit line 122 may be formed as a first conductive layer connected to an active region of the semiconductor substrate 100 through interlayer dielectric films 110 and 120 on the substrate 100 on which cell array devices 102, for example, cell array transistors are formed. A first insulating layer may be formed on the entire surface of the resultant structure using a first insulating material such as Si₃N₄. The first insulating material may be anisotropically etched to form first capping layer 124.

In an example embodiment, an OCS capacitor may further include a first interlayer dielectric film 130 and a second capping layer 134. The first interlayer dielectric film 130 may be formed by forming an insulating film such as an oxide film by chemical vapor deposition (CVD) on the entire surface of the resultant structure using a second insulating material having an etch rate different from that of the first insulating material. The first interlayer dielectric film 130 may be planarized by a chemical mechanical polishing (CMP) process with the first capping layer 124 acting as an etch stop layer. The second capping layer 134 may be formed by forming a second insulating layer on the entire surface of the resultant structure using a third insulating material, for example, Si₃N₄. As shown in FIG. 18, the second capping layer 134 may be planar.

In an example embodiment, an OCS capacitor may further include a plug e1 for forming the storage contact of the cell array region and forming wiring layers e2, e3 and e4 of the peripheral circuit region. In an example embodiment, a second conductive layer may be formed by depositing a metal having excellent filling properties, for example, tungsten (W) or TiN, using CVD.

In an example embodiment, an OCS capacitor may further include a second interlayer dielectric film 140 only in the peripheral circuit region. The second interlayer dielectric film 140 may be formed by forming an insulating film such as an oxide film on the entire surface of the resultant structure and removing the insulating film by etching the insulating film in the cell array region using the second capping layer 134 as an etch stop layer.

In an example embodiment, an OCS capacitor may further include a storage electrode 142 formed to electrically connect to the active region of the substrate 100 through the plug e1 by forming a conductive layer such as a doped polysilicon layer in the cell array region and patterning the conductive layer. It is also possible to form a storage electrode having a structure in which a TiN film and a polysilicon layer are stacked by forming the TiN film and the polysilicon layer and patterning the TiN film and polysilicon layer.

As shown in FIG. 18, an OCS capacitor may include a dielectric film 144, of a dielectric material such as Ta₂O₅ and (Ba, Sr)TiO₃, on the surface of the storage electrode 142 in a cell array region and a plate electrode 146 on the dielectric film 144.

Although example embodiments of the present invention are directed to slurries, polishing methods using the slurries, and method of forming a surface of a capacitor using the slurries, other etching materials may also be used, either in place of, or in addition to the slurries described herein, including, but not limited to etchants that includes a mixture of NH₄F and HF (commonly referred to in the semiconductor processing art as “LaI solutions”) and mixtures of NH₃, H₂O₂ and deionized water (commonly referred to in the semiconductor processing art as an “sc1 solution”).

Although example embodiments of the present invention are directed to polishing ruthenium films, other films, for example, Pt, Ir, RuO₂, IrO₂, SrRuO₃, BaSrRuO₃, or CaSrRuO, may also be polished.

Although example embodiments of the present invention are directed to slurries, slurries with particular classes of components (abrasive, oxidizer, and/or pH controller, etc.), slurries with particular pHs (4, 8, etc), slurries with particular components (colloidal silica, periodic acid, BHMT, etc.), slurries with particular weight percentage ranges of components, slurries with particular weight percentages of components, polishing methods using the slurries, and methods of forming a surface of a capacitor using the slurries, each of the above features may be mixed, matched, and/or interchanged with other features to create numerous, other example embodiments of the present invention.

It will be apparent to those skilled in the art that other changes and modifications may be made in the above-described example embodiments without departing from the scope of the invention herein, and it is intended that all matter contained in the above description shall be interpreted in an illustrative and not a limiting sense.

We claim:

1. A slurry for a chemical mechanical polishing (CMP) method for a film including ruthenium, comprising:
an abrasive;
an oxidizer; and
at least one pH controller to control a pH of the slurry.

2. The slurry of claim 1, wherein the film includes at least one of a ruthenium oxide and a ruthenium alloy.

3. The slurry of claim 1, wherein the pH is in a range from 2 to 8.

4. The slurry of claim 3, wherein the pH is in a range from 3.5 to 4.5.

5. The slurry of claim 4, wherein the pH is about 4.

6. The slurry of claim 1, wherein the at least one pH controller includes an amine.

7. The slurry of claim 6, wherein the at least one pH controller includes at least one material selected from the group consisting of BHMT (Bis-(HexamMethylene)Triamine), TMAH (TetraMethyl Ammonium Hydroxide), TMA (TetraMethylAmine), TEA (TetraEthylAmine), HA (Hydroxylamine), PEA (PolyEthyleneAmine), CH (Choline Hydroxide) and salts thereof.

8. The slurry of claim 7, wherein the at least one pH controller includes TMA.

9. The slurry of claim 8, wherein the slurry includes an amount of TMA such that the pH of the slurry is about 4.

10. The slurry of claim 7, wherein the at least one pH controller includes TMAH.

11. The slurry of claim 10, wherein the slurry includes an amount of TMAH such that the pH of the slurry is about 4.

12. The slurry of claim 11, wherein the abrasive is colloidal silica and the oxidizer is periodic acid.

13. The slurry of claim 12, wherein a content of the periodic acid is in a range from 0.1 to 5 weight % of a total weight of the slurry.

14. The slurry of claim 13, wherein a content of the colloidal silica is in a range from 0.01 to 30 weight % of a total weight of the slurry.

15. The slurry of claim 14, wherein a content of the colloidal silica is in a range from 0.1 to 10 weight % of a total weight of the slurry.

16. The slurry of claim 15, wherein a content of the colloidal silica is in a range from 0.5 to 3 weight % of a total weight of the slurry.

17. The slurry of claim 16, wherein a content of the colloidal silica is 0.5 weight % of a total weight of the slurry and a content of the periodic acid is 0.5 weight % of a total weight of the slurry.

18. The slurry of claim 16, wherein a content of the colloidal silica is 3 weight % of a total weight of the slurry and a content of the periodic acid is 0.5 weight % of a total weight of the slurry.

19. The slurry of claim 1, wherein the at least one pH controller includes potassium hydroxide.

20. The slurry of claim 1, wherein the abrasive includes at least one material selected from the group consisting of ceria, silica, colloidal silica, fumed silica, alumina, titania, angania, zirconia, germania, or mixtures thereof.

21. The slurry of claim 20, wherein a content of the abrasive is in a range from 0.01 to 30 weight % of a total weight of the slurry.

22. The slurry of claim 21, wherein the content of the abrasive is in a range from 0.1 to 10 weight % of a total weight of the slurry.

23. The slurry of claim 1, wherein the oxidizer includes periodic acid.

24. The slurry of claim 23, wherein a content of the periodic acid is in a range from 0.1 to 5 weight % of a total weight of the slurry.

25. The slurry of claim 24, wherein the content of the periodic acid is in a range from 0.5 to 1.5 weight % of a total weight of the slurry.

26. A chemical mechanical polishing (CMP) method for a ruthenium film formed on a semiconductor substrate, the method comprising:
preparing a slurry including an abrasive, an oxidizer, and at least one pH controller to control a pH of the slurry; and
performing chemical mechanical polishing (CMP) of the ruthenium film using the slurry.

27. The method of claim 26, wherein a removal rate selectivity of the slurry is greater than or equal to 5:1.

28. The method of claim 27, wherein a removal rate selectivity of the slurry is greater than or equal to 20:1.

29. The method of claim 28, wherein a removal rate selectivity of the slurry is greater than or equal to 50:1.

30. The method of claim 26, wherein the film includes at least one of a ruthenium oxide and a ruthenium alloy.

31. The method of claim 26, wherein the pH is in a range from 2 to 8.

32. The method of claim 31, wherein the pH is in a range from 3.5 to 4.5.

33. The method of claim 32, wherein the pH is about 4.

34. The method of claim 26, wherein the at least one pH controller includes an amine.

35. The method of claim 34, wherein the at least one pH controller includes at least one material selected from the group consisting of BHMT (Bis-(HexamMethylene)Triamine), TMAH (TetraMethyl Ammonium Hydroxide), TMA (TetraMethylAmine), TEA (TetraEthylAmine), HA (Hydroxylamine), PEA (PolyEthyleneAmine), CH (Choline Hydroxide) and salts thereof.

36. The method of claim 35, wherein the at least one pH controller includes TMA.

37. The method of claim 36, wherein the slurry includes an amount of TMA such that the pH of the slurry is about 4.

38. The method of claim 35, wherein the at least one pH controller includes TMAH.

39. The method of claim 38, wherein the slurry includes an amount of TMAH such that the pH of the slurry is about 4.

40. The method of claim 39, wherein the abrasive is colloidal silica and the oxidizer is periodic acid.

41. The method of claim 40, wherein a content of the periodic acid is in a range from 0.1 to 5 weight % of a total weight of the slurry.

42. The method of claim 41, wherein a content of the colloidal silica is in a range from 0.01 to 30 weight % of a total weight of the slurry.

43. The method of claim 42, wherein a content of the colloidal silica is in a range from 0.1 to 10 weight % of a total weight of the slurry.

44. The method of claim 43, wherein a content of the colloidal silica is in a range from 0.5 to 3 weight % of a total weight of the slurry.

45. The method of claim 44, wherein a content of the colloidal silica is 0.5 weight % of a total weight of the slurry and a content of the periodic acid is 0.5 weight % of a total weight of the slurry.

46. The method of claim 44, wherein a content of the colloidal silica is 3 weight % of a total weight of the slurry and a content of the periodic acid is 0.5 weight % of a total weight of the slurry.

47. The method of claim 26, wherein the at least one pH controller includes potassium hydroxide.

48. The method of claim 26, wherein the abrasive includes at least one material selected from the group consisting of ceria, silica, colloidal silica, fumed silica, alumina, titania, angania, zirconia, germania, or mixtures thereof.

49. The method of claim 48, wherein a content of the abrasive is in a range from 0.01 to 30 weight % of a total weight of the slurry.

50. The method of claim 49, wherein the content of the abrasive is in a range from 0.1 to 10 weight % of a total weight of the slurry.

51. The method of claim 26, wherein the oxidizer includes periodic acid.

52. The method of claim 51, wherein a content of the periodic acid is in a range from 0.1 to 5 weight % of a total weight of the slurry.

53. The method of claim 52, wherein the content of the periodic acid is in a range from 0.5 to 1.5 weight % of a total weight of the slurry.

54. A method for forming a surface for a capacitor comprising:
forming an etch stop layer on a semiconductor substrate;
forming a mold oxide layer on the etch stop layer;
patterning the mold oxide layer to define a region for the capacitor;
forming a layer including ruthenium on the patterned mold oxide layer;
forming a dielectric layer on the layer including ruthenium; and
polishing the layer including ruthenium and the dielectric layer using a slurry including an abrasive, an oxidizer, and at least one pH controller to control a pH of the slurry.

55. The method of claim 54, wherein patterning the mold oxide layer includes using at least one of a hard mask and a photoresist.

56. The method of claim 54, wherein the mold oxide layer is one of PE-TEOS, PE-OX, HDP, USG, and a BPSG layer.

57. The method of claim 54, wherein the layer including ruthenium is deposited by sputtering, by chemical vapor deposition (CVD), or by ALD.

58. The method of claim 54, wherein the dielectric layer includes Ta, Hf, Al, Ti, Sb—Ti (STO), BST oxides or combinations thereof.

59. The method of claim 54, wherein a removal rate selectivity of the slurry is greater than or equal to 5:1.

60. The method of claim 59, wherein a removal rate selectivity of the slurry is greater than or equal to 20:1.

61. The method of claim 60, wherein a removal rate selectivity of the slurry is greater than or equal to 50:1.

62. The method of claim 54, further comprising:
forming a spacer prior to forming the layer including ruthenium.

63. The method of claim 62, wherein the spacer includes Ta, Hf, Al, Ti, Sb—Ti (STO), BST oxides or combinations thereof.

64. The method of claim 54, wherein the capacitor is one of a stacked, concave, or OCS capacitor.

65. The method of claim 54, wherein the layer including ruthenium includes at least one of a ruthenium oxide and a ruthenium alloy.

66. The method of claim 54, wherein the pH is in a range from 2 to 8.

67. The method of claim 66, wherein the pH is in a range from 3.5 to 4.5.

68. The method of claim 67, wherein the pH is about 4.

69. The method of claim 56, wherein the at least one pH controller includes an amine.

70. The method of claim 69, wherein the at least one pH controller includes at least one material selected from the group consisting of BHMT (Bis-(HexamMethylene)Triamine), TMAH (TetraMethyl Ammonium Hydroxide), TMA (TetraMethylAmine), TEA (TetraEthylAmine), HA (Hydroxylamine), PEA (PolyEthyleneAmine), CH (Choline Hydroxide) and salts thereof.

71. The method of claim 70, wherein the at least one pH controller includes TMA.

72. The method of claim 71, wherein the slurry includes an amount of TMA such that the pH of the slurry is about 4.

73. The method of claim 70, wherein the at least one pH controller includes TMAH.

74. The method of claim 73, wherein the slurry includes an amount of TMAH such that the pH of the slurry is about 4.

75. The method of claim 74, wherein the abrasive is colloidal silica and the oxidizer is periodic acid.

76. The method of claim 75, wherein a content of the periodic acid is in a range from 0.1 to 5 weight % of a total weight of the slurry.

77. The method of claim 76, wherein a content of the colloidal silica is in a range from 0.01 to 30 weight % of a total weight of the slurry.

78. The method of claim 77, wherein a content of the colloidal silica is in a range from 0.1 to 10 weight % of a total weight of the slurry.

79. The method of claim 78, wherein a content of the colloidal silica is in a range from 0.5 to 3 weight % of a total weight of the slurry.

80. The method of claim 79, wherein a content of the colloidal silica is 0.5 weight % of a total weight of the slurry and a content of the periodic acid is 0.5 weight % of a total weight of the slurry.

81. The method of claim 80, wherein a content of the colloidal silica is 3 weight % of a total weight of the slurry and a content of the periodic acid is 0.5 weight % of a total weight of the slurry.

82. The method of claim 54, wherein the at least one pH controller includes potassium hydroxide.

83. The method of claim 54, wherein the abrasive includes at least one material selected from the group consisting of ceria, silica, colloidal silica, fumed silica, alumina, titania, angania, zirconia, germania, or mixtures thereof.

84. The method of claim 83, wherein a content of the abrasive is in a range from 0.01 to 30 weight % of a total weight of the slurry.

85. The method of claim 84, wherein the content of the abrasive is in a range from 0.1 to 10 weight % of a total weight of the slurry.

86. The method of claim 54, wherein the oxidizer includes periodic acid.

87. The method of claim 86, wherein a content of the periodic acid is in a range from 0.1 to 5 weight % of a total weight of the slurry.

88. The method of claim 87, wherein the content of the periodic acid is in a range from 0.5 to 1.5 weight % of a total weight of the slurry.
